(19) United States
(12) Patent Application Publication
(10) Pub. No.: US 2025/0146890 A1
(43) Pub. Date: May 8, 2025

(54) A Squeeze Detection System

(71) Applicant: Google LLC, Mountain View, CA (US)

(72) Inventors: Mathieu Simon Le Goc, San Francisco, CA (US); Daniel Husum Cornew, Daly City, CA (US); Christopher Alan Oberhauser, San Jose, CA (US)

(21) Appl. No.: 18/835,936

(22) PCT Filed: Feb. 4, 2022
(86) PCT No.: PCT/US2022/015227

§ 371 Date: Aug. 5, 2024

(51) Int. Cl. G01L 1/14; G01L 5/22

(52) U.S. Cl. CPC G01L 1/14; G01L 5/22

(57) ABSTRACT

A squeeze detection system includes an elongated body extending along a longitudinal direction. The elongated body has a handle. A sensor assembly is positioned within the elongated body proximate the handle. The sensor assembly includes conductive target mounted to the elongated body. An inductive sensor is also mounted to the elongated body. A gap is defined between a coil of the inductive sensor and a target surface of the conductive target. The conductive target and the inductive sensor are mounted to the elongated body such that a size of the gap is changeable in order to detect a squeeze in either a first direction or a second direction within a plane that is perpendicular to the longitudinal direction at the handle of the elongated body. The first and second directions are perpendicular.

### FIELD

The present disclosure relates generally to systems for detecting squeezes. More particularly, the present disclosure relates to a wand, which can detect a user squeezing a handle of the wand.

### BACKGROUND

Certain devices allow a user to input control commands with a switch, a button, etc. However, such user inputs are conspicuous and difficult to conceal. Thus, the user can frequently see and is highly aware of the user input when using inputting control commands. A user input that is inconspicuous and concealable within a device would be useful.

### SUMMARY

Aspects and advantages of embodiments of the present disclosure will be set forth in part in the following description, or may be learned from the description, or may be learned through practice of the embodiments.

Aspects of the present disclosure are directed to a squeeze detection system. An elongated body extends along a longitudinal direction. The elongated body has a handle. A sensor assembly is positioned within the elongated body proximate the handle. The sensor assembly includes a conductive target mounted to the elongated body and an inductive sensor mounted to the elongated body. A gap is defined between a coil of the inductive sensor and a target surface of the conductive target. The conductive target and the inductive sensor are mounted to the elongated body such that a size of the gap is changeable in order to detect a squeeze in either of a first direction and a second direction within a plane that is perpendicular to the longitudinal direction at the handle of the elongated body. The first and second directions are perpendicular.

Aspects of the present disclosure are also directed to a squeeze detection system. An elongated body extends along a longitudinal direction. The elongated body has a handle. A sensor assembly is positioned within the elongated body proximate the handle. The sensor assembly includes a conductive target mounted to the elongated body and an inductive sensor mounted to the elongated body. A gap is defined between a coil of the inductive sensor and a target surface of the conductive target. The conductive target and the inductive sensor are mounted to the elongated body such that a size of the gap is changeable in order to detect a squeeze in any direction within a plane that is perpendicular to the longitudinal direction at the handle of the elongated body. A target surface of the conductive target faces the coil of the inductive sensor. A tangent line from the target surface of the conductive target is oriented about perpendicular to the longitudinal direction.

Aspects of the present disclosure are further directed to a wand. An elongated body extends along a longitudinal direction between a first end portion and a second end portion. The elongated body has a handle positioned proximate the first end portion of the elongated body. A transmitter is positioned within the elongated body proximate the second end portion of the elongated body. A sensor assembly is positioned within the elongated body proximate the first end portion of the elongated body. The sensor assembly includes a conductive target mounted to the elongated body and an inductive sensor mounted to the elongated body. A gap is defined between a coil of the inductive sensor and a target surface of the conductive target. The conductive target and the inductive sensor are mounted to the elongated body such that a size of the gap is changeable in order to detect a squeeze in either of a first direction and a second direction within a plane that is perpendicular to the longitudinal direction at the handle of the elongated body, the first and second directions being perpendicular.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures.

FIG. 1 is a top, plan view of a wand according to an example embodiment of the present subject matter.

FIG. 2 is a partially exploded, perspective view of the example wand of FIG. 1.

FIGS. 3 through 6 are schematic views of certain components of the example wand of FIG. 1 in various deformation states.

FIG. 7 is a top, plan view of a printed circuit board of the example wand of FIG. 1.

FIG. 8 is a partial, perspective view of the example wand of FIG. 1.

FIG. 9 is a perspective, section view of a cylindrical wall and a support leg of the example wand of FIG. 1.

FIG. 10 is a section view of the cylindrical wall and the support leg of the example wand of FIG. 1.

FIG. 11 is a section view of a cylindrical wall and a support leg according to another example embodiment of the present subject matter.

FIG. 12 is a section view of a cylindrical wall and a support leg according to another example embodiment of the present subject matter.

FIG. 13 is a section view of a cylindrical wall and a support leg according to another example embodiment of the present subject matter.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

As used herein, the terms “first,” “second,” and “third” may be used interchangeably to distinguish one component from another and are not intended to signify location or importance of the individual components. The terms “includes” and “including” are intended to be inclusive in a manner similar to the term “comprising.” Similarly, the term “or” is generally intended to be inclusive (i.e., “A or B” is intended to mean “A or B or both”).

Approximating language, as used herein throughout the specification and claims, is applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. For example, the approximating language may refer to being within a ten percent (10%) margin.

Generally, the present disclosure is directed to a squeeze detection system. For instance, a user may grasp and squeeze a handle, and a sensor assembly proximate the handle may detect the squeeze. Moreover, the sensor assembly may include an inductive sensor and a conductive target. As the user grasps and squeezes the handle, relative movement between the inductive sensor and the conductive target may be detected by the inductive sensor.

The squeeze detection system may be positioned within an interactive object, such as a hand-held electronic smart wand. The squeeze detection system may detect when a user squeezes the handle of the wand, and another component of the wand may be activated, deactivated, actuated, triggered, etc. in response to the squeeze detection system detecting the squeeze. For example, a transmitter or receiver, such as an infrared transmitter or infrared receiver, may be activated in response to the squeeze detection system detecting the squeeze. As another example, gesture-recognition software may be activated in response to the squeeze detection system detecting the squeeze. Thus, e.g., after or while squeezing the handle, the user may move the wand in a particular pattern or gesture to initiate an action, such as making a purchase, adjust volume, initiating a special effect, etc.

The inductive sensor and the conductive target may be positioned and oriented to facilitate detection of squeezes from a plurality of directions. For instance, the conductive target and the inductive sensor may be mounted to an elongated body such that a size of a gap between the inductive sensor and the conductive target is changeable in order to detect a squeeze in either of a first direction and a second direction, which are perpendicular to each other. Thus, e.g., the sensor assembly may detect squeezes along at least two different, perpendicular directions. In certain example embodiments, the sensor assembly may be omnidirectional such that sensor assembly may detect squeezes along any direction within a plane perpendicular to a longitudinal direction.

By positioning and/or orienting the inductive sensor and the conductive target to detect squeezes from a plurality of directions, the sensor assembly may advantageously allow a user of the squeeze detection system to squeeze an elongated body along any direction to trigger the sensor assembly. For instance, when installed within a wand, a user may squeeze the handle from any direction to trigger the sensor assembly. Thus, in contrast to a button, switch, etc. on the handle, the user may trigger the sensor assembly with the sensor assembly conspicuously concealed within the wand. The user may advantageously have a “magical” experience while using the wand to trigger an action.

As noted above, the squeeze detection system may be positioned within an interactive object. The interactive object may be a hand-held electronic device that includes various hardware components. For instance, the interactive object may include an elongated body with a wand-like form factor. The wand-like form factor can include a generally cylindrical outer casing with a first end portion, e.g., including a wand tip, and a second end portion, e.g., including a wand handle. The generally cylindrical outer casing may include various diameters, e.g., such that the cylindrical outer casing taperers from the second end portion to the first end portion. In certain example embodiments, the interactive object may include another form-factor such as, e.g., a spherical form-factor. An outer surface of the casing may be textured with a wood pattern, carvings, etc.

The outer casing of the interactive object may form a cavity, which may include various hardware components for performing functions of the interactive object. The hardware components may include, for example: the sensor assembly for detecting a user input, such as a grasp or squeeze; an inertial measurement unit, such as an accelerometer or a gyroscope; a haptic actuator, such as an eccentric rotating mass (ERM) motor; a communication interface, such as a Bluetooth® chip, an antenna, etc.; a microcontroller; a power source, such as a battery with associated charging hardware; output device(s), such as a light emitting diode (LED)/other lights, speakers, etc.; processor(s); memory; and/or other components. The hardware architecture of the interactive object may allow the interactive object to perform various functions including, for example, making a gesture action.

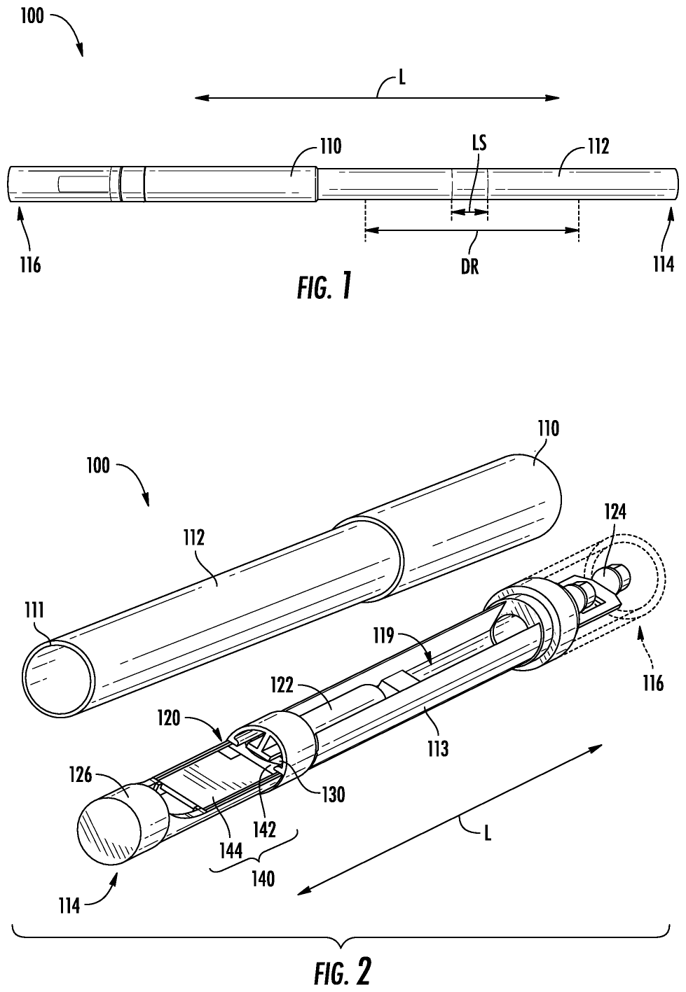

Turning now to FIGS. 1 and 2, a squeeze detection system 100 may include an elongated body 110 and a sensor assembly 120. Elongated body 110 may extend along a longitudinal direction L. Elongated body 110 may have a handle 112. A user may grasp elongated body 110 at handle 112. Sensor assembly 120 may be positioned within elongated body 110 proximate handle 112. Sensor assembly 120 may be configured to detect a user grasping or squeezing handle 112. Moreover, as discussed in greater detail below, sensor assembly 120 may be configured to detect the user grasping or squeezing handle 112 in a plurality of directions. Thus, e.g., sensor assembly 120 may be configured to detect the user grasping or squeezing handle 112 regardless of direction that the user squeezes handle 112.

Squeeze detection system 100 may be incorporated within or configured as an interactive object. As an example, the interactive object may be a hand-held electronic device, such an interactive toy, as shown in FIGS. 1 and 2. Thus, the interactive object may have a wand-like form factor with a generally cylindrical shape. In certain example embodiments, the wand-like form factor of the interactive object may have one or more other shapes, such as square, rectangular, hexagonal, octagonal, etc. In certain example embodiments, the interactive object may have another form-factor, such as a spherical form-factor. The interactive object may be constructed from one or more materials, including polymers, metal, wood, composites, and/or one or more other materials. Sensor assembly 120 may be configured for obtaining user input for the interactive object. For instance, the user input may correspond to when a user physically grips or squeezes handle 112. In certain example embodiments, the interactive object may include one or more additional user inputs, such as buttons, dials, switches, touchpads, light sensors, heat sensors, and/or other features that a user can physically contact to provide user input.

Elongated body 110 may extend, e.g., along the longitudinal direction L, between a first end portion 114 and a second end portion 116. A length of elongated body 110, e.g., along the longitudinal direction L, between first and second end portions 114, 116 may be no less than fifteen millimeters (15 mm) and no greater than one meter (1 m) in certain example embodiments. For instance, the length of elongated body 110 may be about three hundred millimeters (300 mm). Handle 112 may be positioned proximate first end portion 114 of elongated body 110. Thus, a user may grasp and hold handle 112 at first end portion 114 of elongated body 110. Handle 112 may be integrally formed from the outer surface of elongated body 110. As another example, a material suitable for securing or comforting the grip of a user, such as a sleeve, skin, pad, etc., may be applied to or mounted on elongated body 110 proximate first end portion 114 of elongated body 110 to form handle 112.

Elongated body 110 may form an outer casing or shell for various components of squeeze detection system 100, and various components of squeeze detection system 100 may be positioned within elongated body 110. For example, elongated body 110 may define an interior 119. Thus, elongated body 110 may be at least partially hollow between first and second end portions 114, 116 of elongated body 110. Elongated body 110 may include two or more components/pieces that collectively form the outer casing or shell as shown in FIGS. 1 and 2. For instance, an inner support structure may slide into an outer sleeve of elongated body 110.

As noted above, various hardware components for performing the functions of squeeze detection system 100 may be disposed within interior 119. For instance, sensor assembly 120 may be positioned within interior 119 of elongated body 110. As another example, squeeze detection system 100 may include a power source 122 with an associated charging/fueling infrastructure 126 within interior 119 of elongated body 110. For example, the power source 122 may include one or more batteries, such as lithium-ion batteries, lithium-ion polymer batteries, and/or other batteries, and the charging/fueling infrastructure 126 may include wired and/or wireless (e.g., inductive, etc.) charging hardware. As another example, squeeze detection system 100 may include a printed circuit board 144 within interior 119 of elongated body 110. Various hardware components may be mounted on printed circuit board 144 within interior 119 of elongated body 110. For example: an output device, such as light emitting diodes, an ultrasonic transmitter and/or receiver, an infrared transmitter and/or receiver, etc.; a power level gauge configured to indicate a level of power of the squeeze detection system 100; power management integrated circuit(s) configured to manage the power of squeeze detection system 100; microcontroller(s); an inertial measurement unit, such as an accelerometer, a gyroscope, etc.; a haptic actuator, such as an eccentric rotating mass (ERM) motor; memory, such as non-volatile memory chip, flash memory, etc.; a communication interface, such as an antenna; processor(s); and/or other components. In certain example embodiments, output device(s) 124, such as light emitting diodes, an ultrasonic transmitter and/or receiver, an infrared transmitter and/or receiver, etc., may be positioned within interior 119 of elongated body 110 at second end portion 116 of elongated body 110. Thus, output device 124 may be configured to output signals from the second end portion 116 of elongated body 110, e.g., opposite handle 112, to the external environment of squeeze detection system 100. The various hardware components may be removably mounted within elongated body 110 by support structure to facilitate maintenance, replacement, update, etc. of the various hardware components.

As noted above, sensor assembly 120 may be configured to detect a user squeezing handle 112. Sensor assembly 120 may include a conductive target 130 and an inductive sensor 140. Both of conductive target 130 and inductive sensor 140 are mounted to elongated body 110. Inductive sensor 140 may be operable to generate an alternating current (AC) magnetic field at a coil 142 of inductive sensor 140, and the alternating current magnetic field from inductive sensor 140 may generate or increase an eddy current within conductive target 130. The eddy current within conductive target 130 may oppose the alternating current magnetic field from inductive sensor 140, which reduces the inductance of the coil 142. The reduced inductance may in turn change a frequency of the inductive sensor 140. Moreover, the change in frequency may vary as a function of a gap between the coil 142 of inductive sensor 140 and conductive target 130. Thus, the change in frequency may be measured to detect changes in the gap between the coil 142 of inductive sensor 140 and conductive target 130. In certain example embodiments, inductive sensor 140 may include an inductance to digital converter (LDC) chip. Moreover, inductive sensor 140 may include a single or only one inductance to digital converter chip in certain example embodiments.

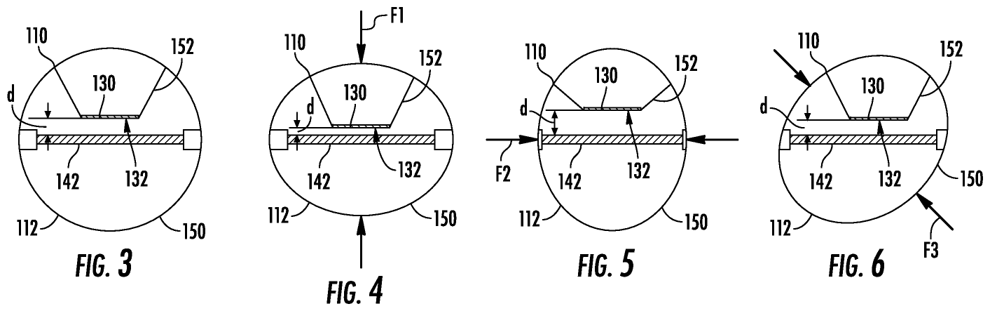

The position and orientation of conductive target 130 and inductive sensor 140 within elongated body 110 may be selected such that sensor assembly 120 may be configured to detect a user squeezing handle 112 in one of a plurality of directions, e.g., in a plane that is perpendicular to the longitudinal direction L. Thus, e.g., sensor assembly 120 may be configured to detect the user squeezing handle 112 regardless of direction that the user squeezes handle 112, e.g., in the plane that is perpendicular to the longitudinal direction L. As shown in FIGS. 3 through 6, a gap D is defined between coil 142 of inductive sensor 140 and a target surface 132 of conductive target 130. Target surface 132 may face coil 142 across gap D, and an alternating current magnetic field from coil 142 may generate or increase an eddy current within conductive target 130 at target surface 132.

The gap D between coil 142 of inductive sensor 140 and target surface 132 of conductive target 130 may ensure that coil 142 does not contact target surface 132 of conductive target 130. However, the gap D may be sized to fit within elongated body 110. For instance, the gap D may be no greater than five millimeters (5 mm), no greater than three millimeters (3 mm), no greater than one millimeter (1 mm), no greater than a half millimeter (0.5 mm), etc. in certain example embodiments.

Coil 142 may include one or more wires wound into a generally planar pattern and mounted on printed circuit board 144. Conductive target 130 may include a metallic foil or metallic plate, e.g., with a width and length that is substantially greater than a thickness of the foil or plate. For instance, conductive target 130 may include a stamped sheet metal body or a metallic tape. As another example, conductive target 130 may include a printed conductive ink pattern. As may be seen from the above, both coil 142 and conductive target 130 may be generally thin, planar structures in certain example embodiments.

Coil 142 of inductive sensor 140 may be positioned about parallel to target surface 132 of conductive target 130. Moreover, a tangent line from target surface 132 of conductive target 130 may be oriented about perpendicular to the longitudinal direction L. Thus, e.g., both of coil 142 and conductive target 130 may be oriented generally perpendicular to the longitudinal direction L. Moreover, e.g., the longitudinal direction L may extend through the gap D between coil 142 of inductive sensor 140 and target surface 132 of conductive target 130 and/or may not intersect both of coil 142 and target surface 132.

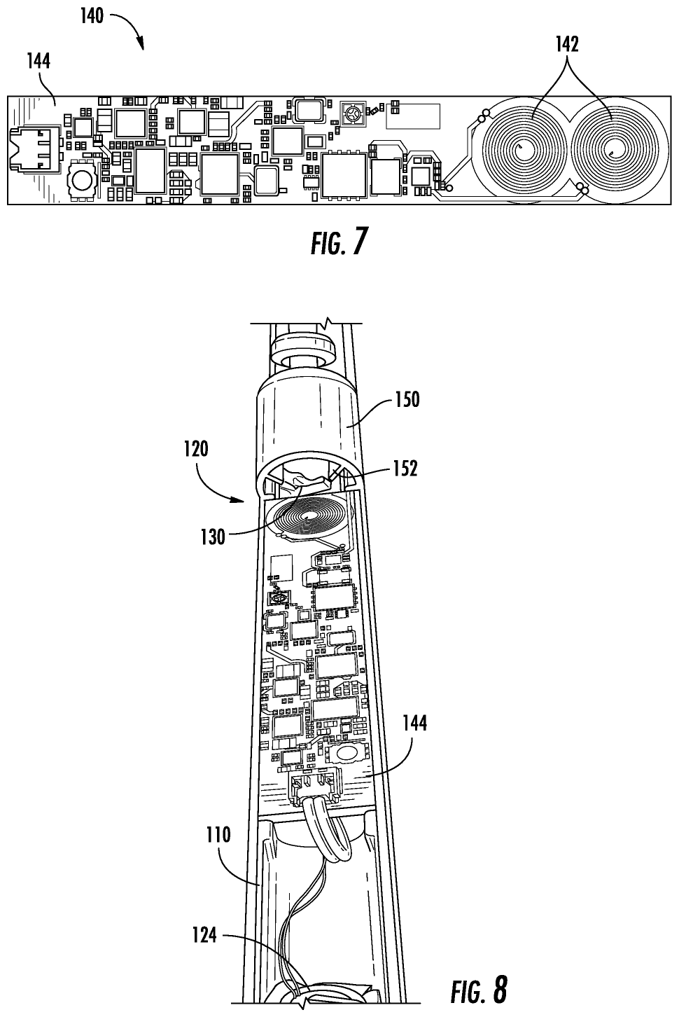

Conductive target 130 and inductive sensor 140 may be mounted to elongated body 110 such that a size of the gap D is changeable in order to detect a squeeze at handle 112 in various directions. Thus, as shown in FIG. 3, the gap D may generally be a first value when a user is not squeezing handle 112. Moreover, e.g., the size of the gap D in FIG. 3 may correspond to a normal, undeformed size of the gap D. Conversely, in FIGS. 4 through 6, the size of gap D is different than the normal, undeformed size of the gap D shown in FIG. 3 because the handle 112 is squeezed to deform the elongated body 110 and thus change the size of the gap D. Moreover, the squeeze is oriented along a first direction F1 in FIG. 4. The gap D in FIG. 4 is larger than the normal, undeformed size of the gap D shown in FIG. 3 because of the deformation of elongated housing 110 caused by the squeeze oriented along the first direction F1. Conversely, the squeeze is oriented along a second direction F2 in FIG. 5, and the second direction F2 is perpendicular to the first direction F1. The gap D in FIG. 5 is smaller than the normal, undeformed size of the gap D shown in FIG. 3 because of the deformation of elongated housing 110 caused by the squeeze oriented along the second direction F2. Moreover, the squeeze is oriented along a third direction F3 in FIG. 6, and the third direction is between the first and second directions F1, F2. The gap D in FIG. 6 is different than the normal, undeformed size of the gap D shown in FIG. 3 because of the deformation of elongated housing 110 caused by the squeeze oriented along the third direction F3.

As may be seen from the above, the position and orientation of conductive target 130 and inductive sensor 140 within elongated body 110 may allow detection of a user squeezing handle 112 in any of the first, second, and third directions F1, F2, F3, each of which is different. Moreover, it will be understood that the position and orientation of conductive target 130 and inductive sensor 140 within elongated body 110 may also allow sensor assembly 120 to detect a user squeezing handle 112 in other directions, e.g., any direction in a plane that is perpendicular to the longitudinal direction L.

As shown in FIGS. 7 through 10, elongated body 110 may include a cylindrical wall 150 and a support leg 152. Handle 112 may be positioned at an outer surface 156 of cylindrical wall 150, and an inner surface 154 of cylindrical wall 150 may face interior 119 of elongated body 110. As an example, handle 112 may be defined at or on outer surface 156 of cylindrical wall 150 in certain example embodiments. As another example, cylindrical wall 150 may be radially nested within handle 112. Support leg 152 may extend from inner surface 154 of cylindrical wall 150, e.g., into interior 119 of elongated body 110. One of conductive target 130 and inductive sensor 140 may be positioned on a mounting plate 158 of support leg 152. For instance, in the example embodiment shown in FIGS. 2 through 10, conductive target 130 is positioned on mounting plate 158, and inductive sensor 140 is positioned on printed circuit board 144. However, it will be understood that the position of conductive target 130 and inductive sensor 140 may be changed in alternative example embodiments.

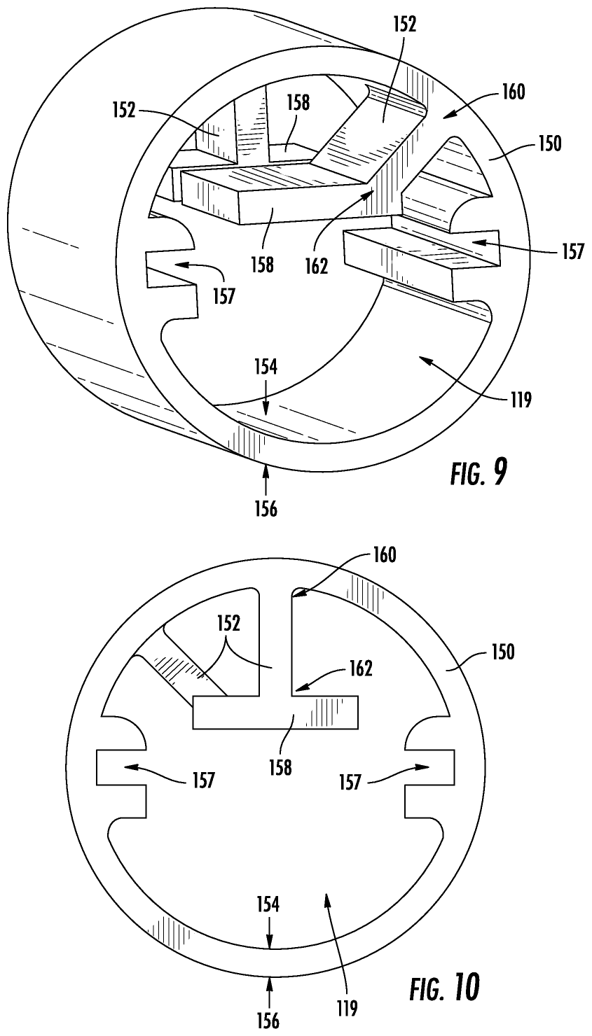

As shown in FIGS. 9 and 10, support leg 152 may be cantilevered from inner surface 154 of cylindrical wall 150. Moreover, support leg 152 may be mounted to cylindrical wall 150 at a proximal end portion 160 of support leg 152, and mounting plate 158 may be positioned at a distal end portion 162 of support leg 152. Such arrangement of support leg 152 may facilitate movement of support leg 152 relative to printed circuit board 144 when a user squeezes handle 112. For instance, each of two, opposite sides of printed circuit board 144 may be received within a respective mounting slot 157 at cylindrical wall 150. Thus, printed circuit board 144 may be mounted to cylindrical wall 150 at slots 157 to form the gap D between coil 142 of inductive sensor 140 and target surface 132 of conductive target 130 described above. Such mounting structure for conductive target 130 and inductive sensor 140 may advantageously facilitate relative movement between conductive target 130 and inductive sensor 140 such that the size of the gap D is changeable to detect squeezes at handle 112 in various directions, e.g., in all direction within the plane that is perpendicular to the longitudinal direction L.

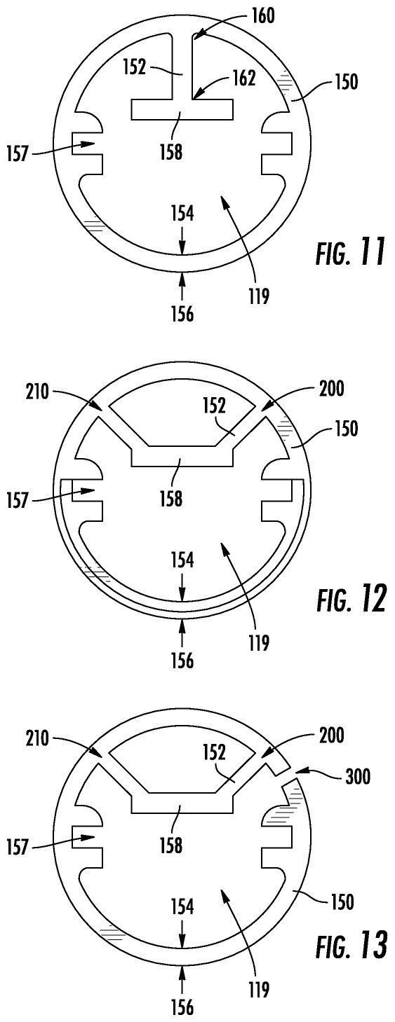

FIGS. 11 through 13 illustrate alternative example embodiments of support leg 152. In the example embodiment shown in FIG. 11, support leg 152 is cantilevered from inner surface 154 of cylindrical wall 150; however, support leg 152 and mounting plate 158 have a T-shaped cross-section in a plane that is perpendicular to the longitudinal direction L. In the example embodiment shown in FIG. 12, support leg 152 is not cantilevered from inner surface 154 of cylindrical wall 150; rather, a first end portion 200 of support leg 152 is mounted to cylindrical wall 150, and a second, opposite end portion 210 of support leg 152 is also mounted to cylindrical wall 150. Mounting plate 158 may be positioned between first and second end portions 200, 210 of support leg 152. In the example embodiment shown in FIG. 13, cylindrical wall 150 defines a slot 300, e.g., at or proximate first end portion 200 of support leg 152. Slot 300 may facilitate deformation of cylindrical wall 150 and thus movement of mounting plate 158 when handle 112 is grasped or squeezed. Slot 300 may thus separate opposite, circumferential edges of cylindrical wall 150.

Turning back to FIG. 1, the mounting structure for conductive target 130 and inductive sensor 140 within elongated body 110 may also advantageously provide for detection of squeezes on handle 112 within a detection range DR, e.g., along the longitudinal direction L. A length of the detection range DR, e.g., along the longitudinal direction L, may be no less than twenty-five millimeters (25 mm) and no greater than three hundred millimeters (300 mm) in certain example embodiments. For example, the length of the detection range DR may be about one hundred millimeters (100 mm). The length of the detection range DR may also be greater than a length of the sensor assembly 120, e.g., along the longitudinal direction L. For instance, length of the sensor assembly 120, e.g., along the longitudinal direction L, may be about fifty millimeters (50 mm). Moreover, the length of the detection range DR, e.g., along the longitudinal direction L, may be no less than two, three, four, five, six, or more times greater than the length of the sensor assembly 120, e.g., along the longitudinal direction L.

As may be seen from the above, sensor assembly 120 may advantageously detect squeezes at various locations on handle 112. Thus, a user need not squeeze a small, single area on handle 112 to trigger sensor assembly 120 by changing the size of the gap D. Moreover, conductive target 130 and inductive sensor 140 may be mounted to elongated body 110 such that the size of the gap D is changeable in order to detect squeezes within a plurality of planes that are perpendicular to the longitudinal direction L, and the plurality of planes may be distributed along the detection range DR. For instance, the plurality of planes may be spaced apart along the longitudinal direction L, and each of the plurality of planes may be located at a respective location on handle 112 along the longitudinal direction L.

As may be seen from the above, squeeze detection system 100 may advantageously detect grips or squeezes on handle 112 from a plurality of directions perpendicular to the longitudinal direction L and along the length of handle 112. Thus, e.g., when utilized within a wand, a user may squeeze handle 112 from many different angles and positions, and sensor assembly 120 will still detect the squeeze, e.g., even when squeeze detection system 100 includes only a single LDC chip. For instance, the position and orientation of conductive target 130 and inductive sensor 140 within elongated body 110 may be generally perpendicular to the longitudinal direction L. Thus, the present subject matter may provide an elongate control device with haptic user input sensing that is robust against variations in touch direction and location.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A squeeze detection system, comprising:
an elongated body extending along a longitudinal direction, the elongated body having a handle; and
a sensor assembly positioned within the elongated body proximate the handle, the sensor assembly comprising
a conductive target mounted to the elongated body, and
an inductive sensor mounted to the elongated body,
wherein a gap is defined between a coil of the inductive sensor and a target surface of the conductive target, and the conductive target and the inductive sensor are mounted to the elongated body such that a size of the gap is changeable in order to detect a squeeze in either of a first direction and a second direction within a plane that is perpendicular to the longitudinal direction at the handle of the elongated body, the first and second directions being perpendicular.

2. The squeeze detection system of claim 1, wherein the elongated body comprises a cylindrical wall and a support leg, the handle positioned at an outer surface of the cylindrical wall, an inner surface of the cylindrical wall facing an interior of the elongated body, the support leg extending from the inner surface of the cylindrical wall into the interior of the elongated body, one of the conductive target and the inductive sensor positioned on a mounting plate of the support leg.

3. The squeeze detection system of claim 2, wherein the support leg is cantilevered from the inner surface of the cylindrical wall such that the support leg is mounted to the cylindrical wall at a proximal end portion of the support leg and the mounting plate is positioned at a distal end portion of the support leg.

4. The squeeze detection system of claim 3, wherein the inductive sensor comprises a printed circuit board, each of a pair of sides of the printed circuit board is received within a respective mounting slot at the cylindrical wall, and the conductive target is positioned on the mounting plate of the support leg.

5. The squeeze detection system of claim 2, wherein a first end portion of the support leg is mounted to the cylindrical wall, a second end portion of the support leg is mounted to the cylindrical wall, and the mounting plate is positioned between the first and second end portions of the support leg.

6. The squeeze detection system of claim 5, wherein the inductive sensor comprises a printed circuit board, each of a pair of sides of the printed circuit board is received within a respective mounting slot at the cylindrical wall, and the conductive target is positioned on the mounting plate of the support leg.

7. The squeeze detection system of claim 6, wherein the cylindrical wall defines a slot that extends along the longitudinal direction such that the mounting plate is moveable relative to the printed circuit board.

8. The squeeze detection system of claim 1, wherein the coil of the inductive sensor is positioned about parallel to the target surface of the conductive target.

9. The squeeze detection system of claim 8, wherein a tangent line from the target surface of the conductive target is oriented about perpendicular to the longitudinal direction.

10. The squeeze detection system of claim 1, wherein a detection range of the handle is no less than twenty-five millimeters along the longitudinal direction, the conductive target and the inductive sensor are mounted to the elongated body such that the size of the gap is changeable in order to detect the squeeze within a plurality of planes that are perpendicular to the longitudinal direction, the plurality of planes distributed along the detection range of the handle.

11. The squeeze detection system of claim 1, wherein the sensor assembly is configured to detect the squeeze in any direction within the plane that is perpendicular to the longitudinal direction at the handle of the elongated body.

12. The squeeze detection system of claim 1, wherein the conductive target comprises a metallic foil or a metallic plate.

13. The squeeze detection system of claim 1, wherein the gap is no greater than five millimeters.

14. (canceled)

15. A squeeze detection system, comprising:
an elongated body extending along a longitudinal direction, the elongated body having a handle; and
a sensor assembly positioned within the elongated body proximate the handle, the sensor assembly comprising
a conductive target mounted to the elongated body, and
an inductive sensor mounted to the elongated body,
wherein a gap is defined between a coil of the inductive sensor and a target surface of the conductive target, the conductive target and the inductive sensor are mounted to the elongated body such that a size of the gap is changeable in order to detect a squeeze in any direction within a plane that is perpendicular to the longitudinal direction at the handle of the elongated body, a target surface of the conductive target faces the coil of the inductive sensor, and a tangent line from the target surface of the conductive target is oriented about perpendicular to the longitudinal direction.

16. A wand, comprising:
an elongated body extending along a longitudinal direction between a first end portion and a second end portion, the elongated body having a handle positioned proximate the first end portion of the elongated body;
a transmitter positioned within the elongated body proximate the second end portion of the elongated body; and
a sensor assembly positioned within the elongated body proximate the first end portion of the elongated body, the sensor assembly comprising
a conductive target mounted to the elongated body, and
an inductive sensor mounted to the elongated body,
wherein a gap is defined between a coil of the inductive sensor and a target surface of the conductive target, and the conductive target and the inductive sensor are mounted to the elongated body such that a size of the gap is changeable in order to detect a squeeze in either of a first direction and a second direction within a plane that is perpendicular to the longitudinal direction at the handle of the elongated body, the first and second directions being perpendicular.

17. The wand of claim 16, wherein the elongated body comprises a cylindrical wall and a support leg, the handle positioned at an outer surface of the cylindrical wall, an inner surface of the cylindrical wall facing an interior of the elongated body, the support leg extending from the inner surface of the cylindrical wall into the interior of the elongated body, one of the conductive target and the inductive sensor positioned on a mounting plate of the support leg.

18. The wand of claim 17, wherein the support leg is cantilevered from the inner surface of the cylindrical wall such that the support leg is mounted to the cylindrical wall at a proximal end portion of the support leg and the mounting plate is positioned at a distal end portion of the support leg.

19. The wand of claim 17, wherein a first end portion of the support leg is mounted to the cylindrical wall, a second end portion of the support leg is mounted to the cylindrical wall, and the mounting plate is positioned between the first and second end portions of the support leg.

20. The wand of claim 16, wherein a detection range of the handle is no less than twenty-five millimeters along the longitudinal direction, the conductive target and the inductive sensor are mounted to the elongated body such that the size of the gap is changeable in order to detect the squeeze within a plurality of planes that are perpendicular to the longitudinal direction, the plurality of planes distributed along the detection range of the handle.
